(19) United States
(12) Patent Application Publication
(10) Pub. No.: US 2026/0107841 A1
(43) Pub. Date: Apr. 16, 2026

(54) MEMORY PACKAGE

(71) Applicant: SAMSUNG ELECTRONICS CO., LTD., Suwon-si (KR)

(72) Inventors: SEOKBEOM YONG, Suwon-si (KR); Eunkyeong PARK, Suwon-si (KR); SUNGOH AHN, Suwon-si (KR)

(73) Assignee: SAMSUNG ELECTRONICS CO., LTD., Suwon-si (KR)

(21) Appl. No.: 19/320,381

(22) Filed: Sep. 5, 2025

(30) Foreign Application Priority Data
Oct. 10, 2024 (KR) 10-2024-0137670

(51) Int. Cl. H01L 25/065; H01L 23/00; H01L 23/498; H01L 23/538; H10B 80/00

(52) U.S. Cl. CPC H10W 90/00; H10B 80/00; H10W 70/611; H10W 90/401; H10W 90/701; H10W 72/859; H10W 90/24; H10W 90/722; H10W 90/724; H10W 90/754

(57) ABSTRACT

A memory package may include a first memory die including: a first substrate; a first wiring layer on a first surface of the first substrate, the first surface being a first active surface; and a first bonding pad on the first wiring layer. The memory package may further include a second memory die including: a second substrate on the first memory die; a second wiring layer between the first surface of the first substrate and a second surface of the second substrate, the second surface being a second active surface; and a second bonding pad on the second wiring layer and electrically connected to the first bonding pad. The memory package may further include a package substrate including a first wire pad electrically connected, by a first wire, to the first bonding pad and the second bonding pad.

### CROSS-REFERENCE TO RELATED APPLICATION

This application claims priority to and the benefit of Korean Patent Application No. 10-2024-0137670, filed in the Korean Intellectual Property Office on Oct. 10, 2024, the entire contents of which are incorporated herein by reference.

### BACKGROUND

### 1. Field

The present disclosure relates to a memory package.

### 2. Description of Related Art

As electronic devices and user systems operated for them become more high-performance, memories with faster speeds and increased capacities are required. It has been attempted to integrate a plurality of memory dies into a single package for increasing the storage capacity of memory, and to increase the number of memory dies loaded into a single channel.

As a method for loading a plurality of memory dies, there is a method for loading a plurality of memory dies by bifurcating a wire pad of a substrate into different wires.

However, if using the above method, wires of different lengths may act as stubs to cause reflection of signals transmitted/received by other wires, which degrades the signal quality transmitted through the wires.

### SUMMARY

The present disclosure attempts to provide a memory package including a plurality of memory dies with improved signal quality.

An embodiment provides a memory package that improves signal quality by reducing wire bifurcation.

According to an embodiment of the present disclosure, a memory package may include a first memory die including: a first substrate; a first wiring layer on a first surface of the first substrate, the first surface being a first active surface; and a first bonding pad on the first wiring layer. The memory package may further include a second memory die including: a second substrate on the first memory die; a second wiring layer between the first surface of the first substrate and a second surface of the second substrate, the second surface being a second active surface; and a second bonding pad on the second wiring layer and electrically connected to the first bonding pad. The memory package may further include a package substrate including a first wire pad electrically connected, by a first wire, to the first bonding pad and the second bonding pad.

According to an embodiment of the present disclosure, a memory package may include a first memory die including a first bonding pad; a second memory die including: a second bonding pad electrically connected to the first bonding pad; and a first input/output pad connected to the second bonding pad by a first redistribution layer. The memory package may further include a third memory die including a third bonding pad, and a fourth memory die including: a fourth bonding pad electrically connected to the third bonding pad; and a second input/output pad connected to the fourth bonding pad by a second redistribution layer. The memory package may further include a package substrate including a wire pad connected, by a first wire, to the first input/output pad, and the wire pad connected, by a second wire, to the second input/output pad.

According to an embodiment of the present disclosure, a memory package may include a first memory die including: a first bonding pad configured to receive a first data signal for a first channel; a second bonding pad configured to receive a second data signal, of a same type as the first data signal, for a second channel different from the first channel; a third bonding pad configured to receive a third data signal, of the same type as the first data signal, for a third channel different from the first channel; a fourth bonding pad configured to receive a fourth data signal, of the same type as the first data signal, for a fourth channel different from the first channel; and a first input/output pad electrically connected to the first bonding pad by a redistribution layer. The memory package may further include a second memory die including: a fifth bonding pad configured to receive the first data signal and electrically connected to the first bonding pad; a sixth bonding pad configured to receive the second data signal and electrically connected to the second bonding pad; a seventh bonding pad configured to receive the third data signal and electrically connected to the third bonding pad; and an eighth bonding pad configured to receive the fourth data signal and electrically connected to the fourth bonding pad. The memory package may further include a package substrate including a first wire connected to the first input/output pad.

### BRIEF DESCRIPTION OF DRAWINGS

FIG. 1 is a perspective view showing a memory package according to an embodiment.

FIG. 2 is a top plan view showing a memory package according to an embodiment.

FIG. 3 is a cross-sectional view along a line A-A′ of FIG. 2.

FIG. 4 is an enlarged view of a region S of FIG. 3.

FIG. 5 illustrates an arrangement of bonding pads in a pad map region according to an embodiment.

FIG. 6 illustrates a bonding relationship between bonding pads according to an embodiment.

FIG. 7 is a cross-sectional view showing a memory package according to an embodiment.

FIG. 8 is a cross-sectional view showing a memory package according to an embodiment.

FIG. 9 is a cross-sectional view showing a memory package according to an embodiment.

FIG. 10 is an enlarged view of a region S′ of FIG. 9.

FIG. 11 illustrates an eye pattern for input/output signals within a memory die according to an embodiment.

FIG. 12 is a block diagram of a memory system according to an embodiment.

FIG. 13 is a block diagram of a storage system according to an embodiment.

### DETAILED DESCRIPTION

Hereinafter, with reference to accompanying drawings, various non-limiting example embodiments of the present disclosure will be described in detail so that a person of an ordinary skill can easily implement embodiments of the present disclosure. Embodiments of the present disclosure may be implemented in many different forms and is not limited to the example embodiments described herein.

In order to clearly explain the present disclosure, parts that are not relevant to the description are omitted, and identical or similar components are assigned the same reference numerals throughout the specification.

In addition, unless explicitly described to the contrary, the word “comprise” (or “include”), and variations such as “comprises” (or “includes”) or “comprising” (or “including”, will be understood to imply the inclusion of stated elements but not the exclusion of any other elements.

In addition, the size and thickness of each component shown in the drawings may be shown arbitrarily for convenience of explanation, so the present disclosure is not necessarily limited to what is shown. In the drawings, the thickness of layers, films, panels, regions, etc., may be exaggerated for clarity. And in the drawings, for convenience of explanation, the thicknesses of some layers and regions may be exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. In addition, being “above” or “on” a reference element does not necessarily mean being positioned “above”in a direction opposite to gravity.

Additionally, when it is described that a component is “connected” or “coupled” to another component, it should be understood not only that the components may be directly connected or coupled to one another, but also that other components may be “interposed” between the components, or components may be “connected” or “coupled” through another component. Also, when it is described that a part is electrically connected (or electrically coupled) to another part, this includes not only cases where they are directly connected, but also cases where they are connected with another element therebetween.

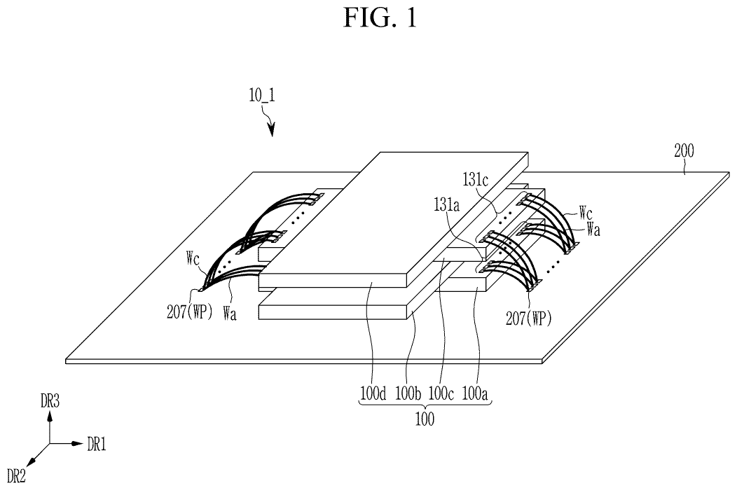

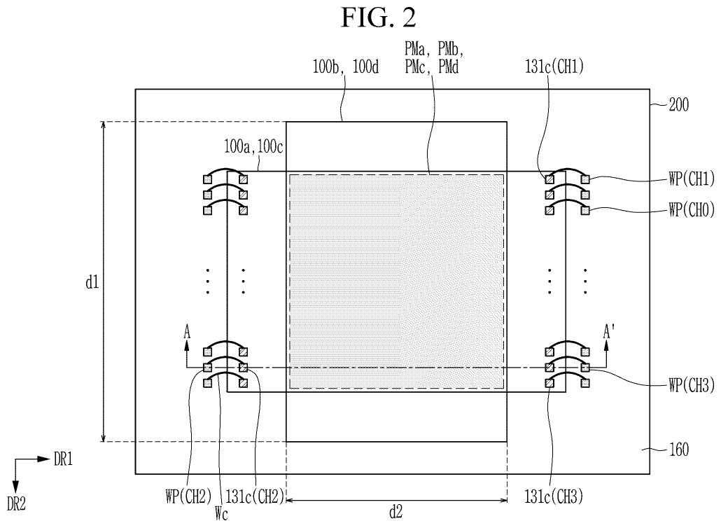

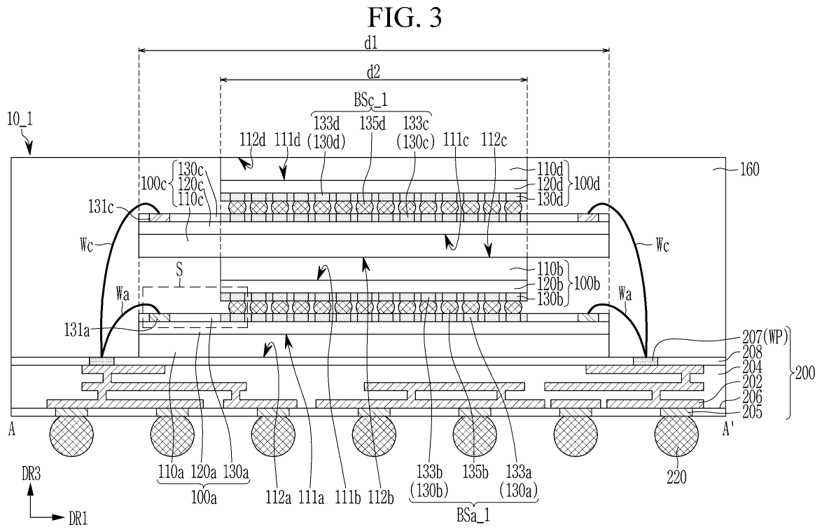

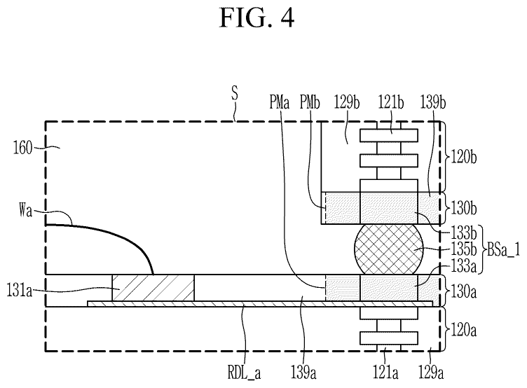

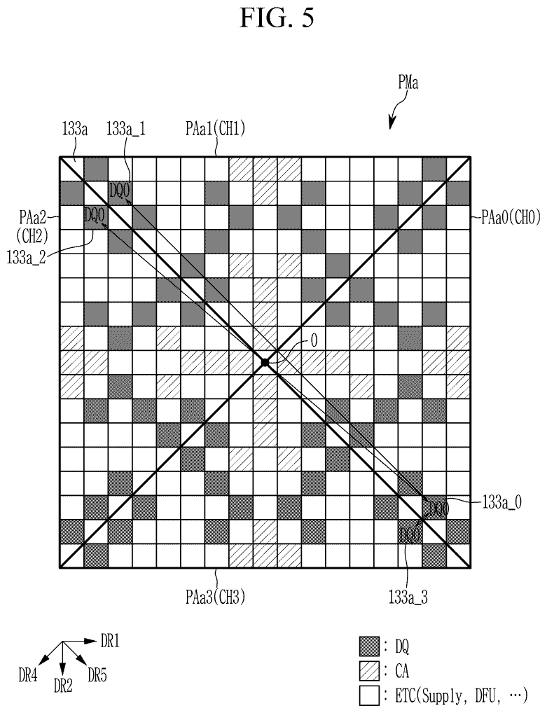

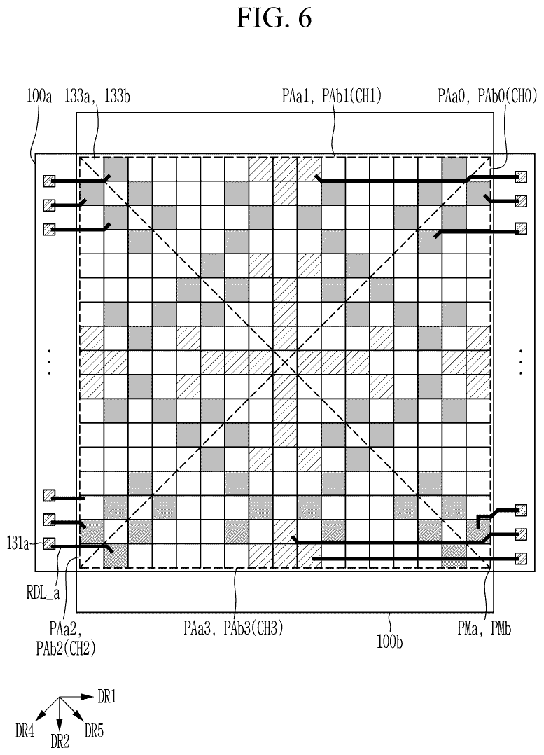

FIG. 1 is a perspective view showing a memory package according to an embodiment. FIG. 2 is a top plan view showing a memory package according to an embodiment. FIG. 3 is a cross-sectional view along a line A-A′ of FIG. 2. FIG. 4 is an enlarged view of a region S of FIG. 3. FIG. 5 illustrates an arrangement of bonding pads in a pad map region according to an embodiment. FIG. 6 illustrates a bonding relationship between bonding pads according to an embodiment.

Specifically, FIG. 5 is a drawing for explaining an arrangement of a plurality of a-th bonding pads 133a in an a-th pad map region PMa of an a-th memory die 100a, and FIG. 6 is a drawing for explaining bonding relationships between a plurality of a-th bonding pads 133a and a plurality of b-th bonding pads 133b in pad map regions PMa and PMb of a-th memory dies 100a and b-th memory dies 100b, respectively.

Referring to FIG. 1 to FIG. 6, a memory package 10_1 may include a memory stacking structure 100 including an a-th memory die 100a, a b-th memory die 100b on the a-th memory die 100a, a c-th memory die 100c on the b-th memory die 100b, and a d-th memory die 100d on the c-th memory die 100c. Additionally, the memory package 10_1 may further include a package substrate 200 on which the memory stacking structure 100 is mounted, external connection terminals 220 provided on a bottom surface of the package substrate 200, and a sealing member 160.

Although the a-th to d-th memory dies 100a to 100d are illustrated as being stacked as a whole in a third direction DR3 in the drawings, in some embodiments, the a-th memory die 100a and the b-th memory die 100b, and the c-th memory die 100c and the d-th memory die 100d may be individually stacked in the third direction DR3.

The memory package 10_1 may be a multi-chip package (MCP) including memory chips of a same type, but embodiments are not limited thereto, and may further include semiconductor chips of different types In some embodiments. In some embodiments, the memory package 10_1 may be a memory device with increased memory capacity by stacking or arranging a plurality of memory dies within a single package. In some embodiments, the memory package 10_1 may input and output data signals in parallel through a memory controller and a plurality of channels. In some embodiments, each channel may have a data width of 16 bits, 32 bits, or 64 bits.

The package substrate 200 may mount the memory stacking structure 100 disposed thereon. The package substrate 200 may redistribute substrate pads 207, which are disposed on the package substrate 200, by extending them to the external region. Thus, the package substrate 200 may be referred to as a redistribution substrate. Additionally, In some embodiments, the package substrate 200 may be referred to as a board, or a board substrate.

In some embodiments, the package substrate 200 may be a ceramic substrate, a printed circuit board (PCB), an organic substrate, an interposer substrate, and the like. Also, In some embodiments, the package substrate 200 may be manufactured based on an active wafer such as a silicon wafer.

In some embodiments, the package substrate 200 may include a wiring structure 202, a substrate insulation layer 204 including the wiring structure 202, and at least one substrate pad 207 disposed on the wiring structure 202 and the substrate insulation layer 204.

The wiring structure 202 may include wiring lines and vias. The wiring lines may be arranged in a multi-layer structure along the third direction DR3, and the wiring lines of layers adjacent in the third direction DR3 may be connected to each other through the vias. At least one external connection terminal 220 may be disposed on a lower surface of the substrate insulation layer 204. The external connection terminals 220 may be disposed on external connection pads 205 and may be connected to the wiring structure 202 through the external connection pads 205. Additionally, the external connection terminals 220 may be electrically connected to the memory stacking structure 100 via the external connection pads 205, the wiring structure 202, and the substrate pads 207.

Among the substrate pads 207, a wire pad WP may be electrically connected to the memory stacking structure 100 through bifurcated wires Wa and Wc. The wire pad WP may input and output signals for the plurality of channels, which are input and output from an external connection terminal 220, to the memory stacking structure 100. In some embodiments, a plurality of wire pads WP may input and output signals for zeroth to third channels CH0 to CH3, which are input and output from at least one external connection terminal 220, to the memory stacking structure 100. Among the signals for the channels, a data signal may be input and output through at least one wire pad WP, and a command address signal may be input through at least one wire pad WP.

The wire pad WP may contain copper (Cu), aluminum (Al), molybdenum (Mo), titanium (Ti), gold (Au), silver (Ag), chromium (Cr), tin (Sn), nickel (Ni), antimony (Sb), bismuth (Bi), zinc (Zn), indium (In), palladium (Pd), platinum (Pt), or an alloy thereof. In some embodiments, the size of the wire pad WP may be 2 to 4 times of the diameter of the wires Wa and Wc. In some embodiments, the diameter of the wire pad WP may be 30 um to 100 um, or 30 um to 45 um. The wire pad WP is illustrated to have a quadrangle shape in a plan view in the drawings, but the shape is not limited thereto, and may be modified into various shapes such as a circle or octagon in some embodiments.

According to some embodiments, the substrate pad 207 may further include a bonding pad, such as a micro bump or a bonding pad bonded in a bump-less bonding, in addition to the wire pad WP.

As shown in FIG. 3, at least one external connection terminal 220 may be disposed on a center region of the lower surface of the substrate insulation layer 204, which overlaps with the memory stacking structure 100 in a plan view, and on a peripheral region of the lower surface of the substrate insulation layer 204 with respect to the center region. The package substrate 200 may perform a function of relocating the external connection terminal 220 on an area wider than the lower surface of the memory stacking structure 100 through the wiring structure 202. In this way, a package structure where the external connection terminal 220 is widely arranged beyond the memory stacking structure 100, for example, beyond the lower surface of the a-th memory die 100a, is called a fan-out (FO) package structure. In some embodiments, the external connection terminal 220 may be a solder ball, but embodiments are not limited thereto.

In some embodiments, the package substrate 200 may be formed at a wafer level and may be included as a component of the memory package 10_1 by separation such as sawing. Such as, if the package substrate 200 is based on a wafer, the memory package 10_1 may be referred to as fan-out wafer level package (FO-WLP). In some embodiments, the package substrate 200 may be formed at a panel level and may be included as a component of the memory package 10_1 by separation such as sawing. Thus, the memory package 10_1 may be referred to as a fan-out panel level package (FO-PLP).

Each of the a-th to d-th memory dies 100a to 100d may be driven as a memory inputting and outputting signals for a plurality of channels, which are input and output from at least one external connection terminal 220. The signals for the plurality of channels may include a data signal, a command address signal, and the like.

In some embodiments, each of the a-th to d-th memory dies 100a to 100d may be a quad channel memory and may input and output data signals of the zeroth to third channels CH0 to CH3 from the external connection terminals 220. In some embodiments, the a-th to d-th memory dies 100a to 100d may be identical memory dies and may be manufactured by performing the same processes except for some redistribution processes.

In some embodiments, the a-th to d-th memory dies 100a to 100d may be volatile memory devices and may be implemented as static random access memory (SRAM), dynamic random access memory (DRAM), etc.

In some embodiments, the a-th to d-th memory dies 100a to 100d may be non-volatile memory devices, and may be implemented as flash memory device, phase change RAM (PRAM), magnetic RAM (MRAM), resistive RAM (RRAM, ferroelectric RAM (FRAM), Thyristor RAM (TRAM), read only memory (ROM), programmable ROM (PROM), electrically erasable and programmable ROM (EEPROM), etc. In some embodiments, when the a-th to d-th memory dies 100a to 100d are non-volatile memory devices, the memory package 10_1 may further include a buffer chip mounted on the package substrate 200.

In some embodiments, the a-th to d-th memory dies 100a to 100d may be chips having the same area as each other in a plan view. The a-th memory die 100a may have a long side of a first length d1 extending in a first direction DR1 and a short side of a second length d2 extending in a second direction DR2, and the first length d1 may be longer than the second length d2. The b-th memory die 100b may have a short side of the second length d2 extending in the first direction DR1 and a long side of the first length d1 extending in the second direction DR2. The c-th memory die 100c may have a long side of the first length d1 extending in the first direction DR1 and a short side of the second length d2 extending in the second direction DR2. The d-th memory die 100d may have a short side of the second length d2 extending in the first direction DR1 and a long side of the first length d1 extending in the second direction DR2.

The a-th memory die 100a may include an a-th substrate 110a, an a-th wiring layer 120a, and an a-th pad layer 130a.

The a-th substrate 110a may have a first surface 111a and a second surface 112a which are opposed to each other. The first surface 111a may be an active surface and may face the b-th memory die 100b. The second surface 112a may be an inactive surface and may face the package substrate 200. As an active surface of the a-th substrate 110a, memory elements or circuit elements may be disposed on the first surface 111a of the a-th substrate 110a. The first surface 111a may be referred to as a front surface where the memory elements or circuit elements are arranged, and the second surface 112a may be referred to as a rear surface.

The a-th substrate 110a may contain bulk silicon, silicon-on-insulator (SOI), silicon germanium, silicon germanium on insulator (SGOI), indium antimony, lead tellurium compound, indium arsenic, indium phosphide, gallium arsenic, or gallium antimony.

The a-th first wiring layer 120a may be disposed on the first surface 111a and may include an a-th insulation layer 129a including a plurality of buffer films and a plurality of insulation films which are arranged alternately in the third direction DR3. For example, the buffer film may contain silicon nitride, silicon carbon nitride, SiCON, etc. The insulation film may contain silicon oxide, carbon doped silicon oxide, silicon carbon nitride (SiCN), etc. In some embodiments, the plurality of buffer films and the plurality of insulation films may be disposed as a single material layer.

The a-th wiring layer 120a may include an a-th wiring structure 121a of a multi-layer structure therein. For example, the a-th wiring structure 121a may include, a plurality of wiring lines vertically stacked in the third direction DR3 in the a-th insulation layer 129a, and a plurality of vias connecting the stacked plurality of wiring lines.

The a-th wiring structure 121a may contain a conductive metallic material such as, for example, aluminum (Al), copper (Cu), tin (Sn), nickel (Ni), gold (Au), platinum (Pt), or an alloy thereof.

The a-th pad layer 130a may be disposed on the a-th wiring layer 120a. The a-th pad layer 130a may include a plurality of a-th input/output pads 131a, a plurality of a-th bonding pads 133a, an a-th redistribution layer RDL_a, and an a-th passivation film 139a.

At least a portion of the plurality of a-th input/output pads 131a and the plurality of a-th bonding pads 133a may be exposed by the a-th passivation film 139a. According to some embodiments, the a-th passivation film 139a may include a plurality of laminated insulation films. For example, the a-th passivation film 139a may include an organic passivation film including an oxide film, and an inorganic passivation film including a nitride film, which are sequentially laminated. The a-th passivation layer 139a may contain silicon oxide, silicon nitride, silicon nitride, silicon carbon nitride, and the like.

The plurality of a-th bonding pads 133a may be connected to the a-th wiring structure 121a of the a-th wiring layer 120a, and may input/output signals received from the a-th wiring structure 121a.

The plurality of a-th bonding pads 133a may be arranged in the a-th pad map region PMa, which includes a center O of the first surface 111a, within the a-th pad layer 130a. The plurality of a-th input/output pads 131a may be arranged in a non-overlapping manner with the a-th pad map region PMa in the a-th pad layer 130a.

The a-th pad map region PMa may overlap with the b-th pad map region PMb of the opposing b-th memory die 100b, in a plan view. The b-th pad map region PMb will be described later. The plurality of a-th input/output pads 131a may be arranged on the a-th wiring layer 120a so as not to overlap with b-th memory die 100b in a plan view.

The plurality of a-th input/output pad 131a may be electrically connected to at least one wire pad WP via at least one a-th wire Wa. In some embodiments, the plurality of a-th input/output pads 131a may input/output signals of the zeroth to third channels CH0 to CH3, which may be input and output from the at least one wire pad WP, to the a-th memory die 100a and the b-th memory die 100b. Among the signals for the channel, a data signal may be input/output through the plurality of a-th input/output pads 131a, and a command address signal may be input through the plurality of a-th input/output pads 131a.

The plurality of a-th input/output pad 131a may contain copper (Cu), aluminum (Al), molybdenum (Mo), titanium (Ti), gold (Au), silver (Ag), chromium (Cr), tin (Sn), nickel (Ni), antimony (Sb), bismuth (Bi), zinc (Zn), indium (In), palladium (Pd), platinum (Pt), or an alloy thereof. In some embodiments, the size of each plurality of a-th input/output pads 131a may be 2 to 4 times of the diameter of the a-th wire Wa. In some embodiments, the diameter of the plurality of a-th input/output pads 131a may be 30 um to 100 um, or 30 um to 45 um. The plurality of a-th input/output pads 131a may have a shape of a quadrangle in a plan view, but embodiments are not limited thereto, and may be modified into various shapes such as a circle or an octagon, In some embodiments.

The a-th wire Wa may contain gold (Au), copper (Cu), aluminum (Al), or an alloy thereof. The diameter for the a-th wire Wa may be 15 um to 50 um, or 15 um to 35 um.

The a-th redistribution layer RDL_a may be interposed between the a-th wiring layer 120a and the a-th passivation film 139a. The a-th redistribution layer RDL_a may extend on the a-th wiring layer 120a, and may electrically connect the a-th input/output pad 131a, a corresponding a-th bonding pad 133a, and the a-th wiring structure 121a. For example, if the a-th redistribution layer RDL_a may be connected to an a-th input/output pad 131a which inputs/outputs the zeroth data signal of the zeroth channel CH0, the a-th redistribution layer RDL_a may be connected to an a-th bonding pad 133a which inputs/outputs the zeroth data signal of the zeroth channel CH0. The a-th redistribution layer RDL_a may contain a conductive metallic material such as, for example, aluminum (Al), copper (Cu), tin (Sn), nickel (Ni), gold (Au), platinum (Pt), or an alloy thereof.

A plurality of a-th bonding pad 133a may input/output signals for the zeroth to third channels CH0 to CH3, which may be input/output from the plurality of a-th input/output pad 131a, to the a-th memory die 100a and the b-th memory die 100b.

The plurality of a-th bonding pads 133a may be respectively disposed at a specific position in the a-th pad map region PMa depending on the input/output signals.

In an example of FIG. 5, the a-th pad map region PMa may be a square shape of which the lengths of perpendicular sides are the same, and the a-th pad map region PMa may include the a_0-th to a_3-th pad regions PAa0 to PAa3, which are distinguished from each other, by a first diagonal direction DR4 and a second diagonal direction DR5. In some embodiments, each of the a_0-th to a_3-th pad regions PAa0 to PAa3 may have an isosceles right triangle shape.

A plurality of a-th bonding pads 133a for inputting/outputting signals for the zeroth channel CH0 may be arranged in the a_0-th pad region PAa0. A plurality of a-th bonding pads 133a for inputting/outputting signals for the first channel CH1 may be arranged in the a_1-th pad region PAa1. A plurality of a-th bonding pads 133a for inputting/outputting signals for the second channel CH2 may be arranged in the a_2-th pad region PAa2. A plurality of a-th bonding pads 133a for inputting/outputting signals for the third channel CH3 may be arranged in the a_3-th pad region PAa3. In some embodiments, a plurality of a-th bonding pads 133a inputting/outputting a common signal for the zeroth to third channels CH0 to CH3 or a signal irrelevant to the zeroth to third channels CH0 to CH3 may be variously arranged within the a-th pad map region PMa. In some embodiments, at least some of the plurality of a-th bonding pads 133a may receive power signals regardless of the zeroth to third channels CH0 to CH3, or may not input and output any signal.

Two of the a-th bonding pads 133a, which are mirrored according to different channels and input/output the same type of signal, may be arranged in a point symmetry with respect to the center O in the a-th pad map region PMa. Also, two of the a-th bonding pads 133a, which are mirrored according to different channels and input/output the same type of signal, may be symmetrically arranged with respect to the first diagonal direction DR4 or the second diagonal direction DR5 in the a-th pad map region PMa. In the present disclosure, the same type signals may be defined as signals that are the same at the netlist level.

In an example of FIG. 5, the plurality of a-th bonding pads 133a may include an a_0-th bonding pad 133a_0 inputting/outputting the zeroth data signal DQ of the zeroth channel CH0, an a_1-th bonding pad 133a_1 inputting/outputting the zeroth data signal DQ of the first channel CH1, an a_2-th bonding pad 133a_2 inputting/outputting the zeroth data signal DQ of the second channel CH2, and an a_3-th bonding pad 133a_3 inputting/outputting the zeroth data signal DQ of the third channel CH3. The a_0-th bonding pad 133a_0 and the a_1-th bonding pad 133a_1 may be arranged symmetrically each other with respect to the first diagonal direction DR4. The a_0-th bonding pad 133a_0 and the a_3-th bonding pad 133a_3 may be arranged symmetrically each other with respect to the second diagonal direction DR5. The a_0-th bonding pad 133a_0 and the a_2-th bonding pad 133a_2 may be arranged in a point symmetry with respect to the center O. The a_0-th to a_3-th bonding pads 133a_0 to 133a_3 may be defined as the same ports at the netlist level.

The a-th bonding pad 133a may have a pillar shape, and may contain a conductive metallic material, such as copper (Cu), aluminum (Al), molybdenum (Mo), titanium (Ti), gold (Au), silver (Ag), chromium (Cr), tin (Sn), nickel (Ni), antimony (Sb), bismuth (Bi), zinc (Zn), indium (In), palladium (Pd), platinum (Pt), or an alloy thereof.

The plurality of a-th bonding pads 133a are illustrated as a quadrangle in a plan view in the drawing, but embodiments are not limited thereto, and the plurality of a-th bonding pads 133a may be modified into various shapes such as a circle or an octagon, in some embodiments. In FIG. 5, adjacent a-th bonding pads 133a of the plurality of a-th bonding pads 133a are arranged so as not to be spaced apart from each other, but embodiments are not limited thereto, and a-th bonding pads 133a that are adjacent to each other may be arranged apart from each other.

The b-th memory die 100b may include an b-th substrate 110b, an b-th wiring layer 120b, and am b-th pad layer 130b.

The b-th substrate 110b may have a third surface 111b and a fourth surface 112b which are opposed to each other. The third surface 111b may be an active surface and may face the a-th memory die 100a. The fourth surface 112b may be an inactive surface and may face the c-th memory die 100c disposed thereon. As an active surface of the b-th substrate 110b, memory elements or circuit elements may be disposed on the third surface 111b of the b-th substrate 110b. The third surface 111b may be referred to as a front surface where the memory elements or circuit elements are disposed, and the fourth surface 112b may be referred to as a rear surface.

The b-th substrate 110b may contain bulk silicon, SOI, silicon germanium, SGOI (silicon germanium on insulator), indium antimony, lead tellurium compound, indium arsenic, indium phosphide, gallium arsenic, or gallium antimony.

The b-th first wiring layer 120b may be disposed on the third surface 111b and may include an b-th insulation layer 129b including a plurality of buffer films and a plurality of insulation films which are arranged alternately in the third direction DR3. For example, the buffer film may contain silicon nitride, silicon carbon nitride, SiCON, etc. The insulation film may contain silicon oxide, carbon doped silicon oxide, silicon carbon nitride (SiCN), etc. In some embodiments, the plurality of buffer films and the plurality of insulation films may be disposed as a single material layer.

The b-th wiring layer 120b may include a b-th wiring structure 121b of a multi-layer structure therein. For example, the b-th wiring structure 121b may include, a plurality of wiring lines vertically stacked in the third direction DR3 in the b-th insulation layer 129b, and a plurality of vias connecting the stacked plurality of wiring lines.

The b-th wiring structure 121b may contain a conductive metallic material such as, for example, aluminum (Al), copper (Cu), tin (Sn), nickel (Ni), gold (Au), platinum (Pt), or an alloy thereof.

The b-th pad layer 130b may be disposed on the b-th wiring layer 120b. The b-th pad layer 130b may include a plurality of b-th bonding pads 133b and a b-th passivation film 139b.

At least a portion of the plurality of b-th bonding pads 133b may be exposed by the b-th passivation film 139b. According to some embodiments, the b-th passivation film 139b may include a plurality of laminated insulation films. For example, the b-th passivation film 139b may include an organic passivation film including an oxide film, and an inorganic passivation film including a nitride film, which are sequentially laminated. The b-th passivation layer 139b may contain silicon oxide, silicon nitride, silicon nitride, silicon carbon nitride, and the like.

A plurality of b-th bonding pads 133b may be connected to the b-th wiring structure 121b of the b-th wiring layer 120b, and may input/output signals received from the b-th wiring structure 121b.

A plurality of b-th bonding pads 133b may be arranged in the b-th pad map region PMb, which includes a center of the third surface 111b, within the b-th pad layer 130b. The b-th pad map region PMb may overlap with the a-th pad map region PMa of the opposing a-th memory die 100a, in a plan view.

In an example of FIG. 6, the b-th pad map region PMb may be a square shape of which the lengths of perpendicular sides are the same, and the b-th pad map region PMb may include the b_0-th to b_3-th pad regions PAb0 to PAb3, which may be distinguished from each other by the first diagonal direction DR4 and the second diagonal direction DR5. In some embodiments, each of the b_0-th to b_3-th pad regions PAb0 to PAb3 may have an isosceles right triangle shape.

A plurality of b-th bonding pads 133b for inputting/outputting signals for the zeroth channel CH0 may be arranged in the b_0-th pad region PAb0. A plurality of b-th bonding pads 133b for inputting/outputting signals for the first channel CH1 may be arranged in the b_1-th pad region PAb1. A plurality of b-th bonding pads 133b for inputting/outputting signals for the second channel CH2 may be arranged in the b_2-th pad region PAb2. A plurality of b-th bonding pads 133b for inputting/outputting signals for the third channel CH3 may be arranged in the b_3-th pad region PAb3.

The b_0-th pad region PAb0 may be aligned with the a_0-th pad region PAa0 in the third direction DR3 so as to overlap with the a_0-th pad region PAa0 in a plan view. The b_1-th pad region PAb1 may be aligned with the a_1-th pad region PAa1 in the third direction DR3 so as to overlap with the a_1-th pad region PAa1 in a plan view. The b_2-th pad region PAb2 may be aligned with the a_2-th pad region PAa2 in the third direction DR3 so as to overlap with the a_2-th pad region PAa2 in a plan view. The b_3-th pad region PAb3 may be aligned with the a_3-th pad region PAa3 in the third direction DR3 so as to overlap with the a_3-th pad region PAa3 in a plan view.

The b-th bonding pad 133b and the a-th bonding pad 133a, which input/output the same type of signal for the same channel, may be aligned in the third direction DR3 to overlap with each other in a plan view. In an example of FIG. 6, a plurality of b-th bonding pads 133b may include an b_0-th bonding pad 133b_0 inputting/outputting the zeroth data signal DQ of the zeroth channel CH0, an b_1-th bonding pad 133b_1 inputting/outputting the zeroth data signal DQ of the first channel CH1, an b_2-th bonding pad 133b_2 inputting/outputting the zeroth data signal DQ of the second channel CH2, and an b_3-th bonding pad 133b_3 inputting/outputting the zeroth data signal DQ of the third channel CH3. The b_0-th bonding pad 133b_0 may be disposed to overlap with the a_0-th bonding pad 133a_0 in the third direction DR3, the b_1-th bonding pad 133b_1 may be disposed to overlap with the a_1-th bonding pad 133a_1 in the third direction DR3, the b_2-th bonding pad 133b_2 may be disposed to overlap with the a_2-th bonding pad 133a_2 in the third direction DR3, and the b_3-th bonding pad 133b_3 may be disposed to overlap with the a_3-th bonding pad 133a_3 in the third direction DR3.

The b-th bonding pad 133b may have a pillar shape, and may contain a conductive metallic material, such as copper (Cu), aluminum (Al), molybdenum (Mo), titanium (Ti), gold (Au), silver (Ag), chromium (Cr), tin (Sn), nickel (Ni), antimony (Sb), bismuth (Bi), zinc (Zn), indium (In), palladium (Pd), platinum (Pt), or an alloy thereof.

The plurality of b-th bonding pads 133b are illustrated as a quadrangle in a plan view in the drawing, but embodiments are not limited thereto, and the plurality of b-th bonding pads 133b may be modified into various shapes such as a circle or an octagon, In some embodiments. In FIG. 6, adjacent b-th bonding pads 133b of the plurality of b-th bonding pads 133b are arranged so as not to be spaced apart from each other, but embodiments are not limited thereto, and a plurality of b-th bonding pads 133b that are adjacent to each other may be arranged apart from each other.

The a-th bonding pad 133a and the b-th bonding pad 133b, which are aligned in the third direction DR3 to overlap with each other in a plan view, may be electrically connected to each other, and the a-th bonding pad 133a and the b-th bonding pad 133b, which are aligned in the third direction D3 and overlapped in a plan view, may be bonded through a b-th bump 135b. The b-th bump 135b may be a micro bump including a metal layer formed by a plating method, but embodiments are not limited thereto. The a-th bonding pad 133a, the b-th bonding pad 133b, and the b-th bump 135b may form an a-th bonding structure BSa_1 for the a-th memory die 100a and the b-th memory die 100b. The a-th bonding structure BSa_1 may be electrically connected to a plurality of a-th input/output pads 131a and the a-th redistribution layer RDL_a.

Through the symmetrical arrangement of the plurality of b-th bonding pads 133b according to channels within the b-th pad map region PMb and the symmetrical arrangement of the plurality of a-th bonding pads 133a according to channels within the a-th pad map region PMa, the plurality of a-th bonding pads 133a and the plurality of b-th bonding pads 133b, which correspond to one another, may be aligned in the third direction DR3 and electrically connected. Through the arrangement of the bonding pads within the pad map region, even if the b-th memory die 100b is rotated and flipped to be connected to the a-th memory die 100a, the corresponding plurality of a-th bonding pads 133a and the plurality of b-th bonding pads 133b may be connected to each other as a part of the a-th bonding structure BSa_1.

Signals input/output through the plurality of a-th input/output pads 131a may be bifurcated and input/output to the a-th memory die 100a and the b-th memory die 100b through the a-th bonding structure BSa_1, without bifurcating through a separate wire.

The c-th memory die 100c may include a c-th substrate 110c, a c-th wiring layer 120c, and a c-th pad layer 130c. The d-th memory die 100d may include a d-th substrate 110d, a d-th wiring layer 120d, and a d-th pad layer 130d. Each of the c-th memory die 100c and the d-th memory die 100d may correspond to each of the a-th memory die 100a and the b-th memory die 100b. Additionally, each of the c-th substrate 110c, the c-th wiring layer 120c, the c-th pad layer 130c, the d-th substrate 110d, the d-th wiring layer 120d, and the d-th pad layer 130d may correspond to each of the a-th substrate 110a, the a-th wiring layer 120a, the a-th pad layer 130a, the b-th substrate 110b, the b-th wiring layer 120b, and the b-th pad layer 130b. For convenience of description, the c-th memory die 100c and the d-th memory die 100d will be described by focusing on the differences in the corresponding configurations.

The c-th substrate 110c may have a fifth surface 111c and a sixth surface 112c which are opposed to each other. The fifth surface 111c may be an active surface and may face the d-th memory die 100d. The sixth surface 112c may be an inactive surface and may face the b-th memory die 100b. As an active surface of the c-th substrate 110c, memory elements or circuit elements may be disposed on the fifth surface 111c of the c-th substrate 110c. The fifth surface 111c may be referred to as a front surface where the memory elements or circuit elements are disposed, and the sixth surface 112c may be referred to as a rear surface.

The c-th first wiring layer 120c may be disposed on the fifth surface 111c and the c-th pad layer 130c may be disposed on the c-th wiring layer 120c. The c-th pad layer 130c may include a plurality of c-th input/output pads 131c, a plurality of c-th bonding pads 133c, a redistribution layer connecting the plurality of c-th input/output pads 131c and the plurality of c-th bonding pads 133c, and a passivation film exposing portions of the plurality of c-th input/output pads 131c and the plurality of c-th bonding pads 133c.

A plurality of c-th bonding pads 133c may be arranged in a c-th pad map region PMc, which includes a center of the fifth surface 111c, within the c-th pad layer 130c. A plurality of c-th input/output pads 131c may be arranged in a non-overlapping manner with the c-th pad map region PMa in the c-th pad layer 130c.

The c-th pad map region PMc may overlap with a d-th pad map region PMd of the opposing d-th memory die 100d, in a plan view. A plurality of c-th input/output pads 131c may be arranged on the c-th wiring layer 120c so as not to overlap d-th memory die 100d in a plan view.

A plurality of c-th input/output pads 131c may be electrically connected to at least one wire pad WP via at least one c-th wire Wc. In some embodiments, a plurality of c-th input/output pads 131c may input/output signals of the zeroth to third channels CH0 to CH3, which are input and output from the at least one wire pad WP, to the c-th memory die 100c and the d-th memory die 100d. Among the signals for the channel, a data signal may be input/output through the plurality of c-th input/output pads 131c, and a command address signal may be input through the plurality of c-th input/output pads 131c.

A plurality of c-th bonding pads 133c may input/output signals for the zeroth to third channels CH0 to CH3, which may be input/output from the plurality of c-th input/output pad 131c, to the c-th memory die 100c and the d-th memory die 100d.

The plurality of c-th bonding pads 133c may be respectively disposed at a specific position in the c-th pad map region PMc depending on the input/output signals. Two of the c-th bonding pads 133c, which are mirrored according to different channels and input/output the same type of signal, may be arranged in a point symmetry with respect to a center in the c-th pad map region PMc. Also, two of the c-th bonding pads 133c, which are mirrored according to different channels and input/output the same type of signal, may be symmetrically arranged with respect to the first diagonal direction DR4 or the second diagonal direction DR5 in the c-th pad map region PMc. The same type of signal may be defined as the signals same at the netlist level.

The d-th substrate 110d may have a seventh surface 111d and a eighth surface 112d which are opposed to each other. The seventh surface 111d may be an active surface and may face the c-th memory die 100c. The eighth surface 112d may be an inactive surface and may face the c-th memory die 100c. As an active surface of the d-th substrate 110d, memory elements or circuit elements may be disposed on the seventh surface 111d of the d-th substrate 110d. The seventh surface 111d may be referred to as a front surface where the memory elements or circuit elements are disposed, and the eighth surface 112d may be referred to as a rear surface.

The d-th first wiring layer 120d may be disposed on the seventh surface 111d and the d-th pad layer 130d may be disposed on the d-th wiring layer 120d. The d-th pad layer 130d may include a plurality of d-th bonding pads 133d and a passivation film exposing portions of the plurality of d-th bonding pads 133d.

A plurality of d-th bonding pads 133d may be arranged in the d-th pad map region PMd, which includes a center of the seventh surface 111d, within the d-th pad layer 130d. The d-th pad map region PMd may overlap with the c-th pad map region PMc of the opposing c-th memory die 100c, in a plan view.

The plurality of d-th bonding pads 133d may be respectively disposed at a specific position in the d-th pad map region PMd depending on the input/output signals. Two of the d-th bonding pads 133d, which are mirrored according to different channels and input/output the same type of signal, may be arranged in a point symmetry with respect to a center in the d-th pad map region PMd. Also, two of the d-th bonding pads 133d, which are mirrored according to different channels and input/output the same type of signal, may be symmetrically arranged with respect to the first diagonal direction DR4 or the second diagonal direction DR5 in the d-th pad map region PMd. The same type of signal may be defined as signals that are the same at the netlist level.

The d-th bonding pad 133d and the c-th bonding pad 133c, which input/output the same type of signal for the same channel, may be aligned in the third direction DR3 to overlap with each other in a plan view.

The c-th bonding pad 133c and the d-th bonding pad 133d, which are aligned in the third direction DR3 to overlap with each other in a plan view, may be electrically connected to each other, and the c-th bonding pad 133c and the d-th bonding pad 133d, which are aligned in the third direction D3 and overlapped in a plan view, may be bonded through a d-th bump 135d. The d-th bump 135d may be a micro bump including a metal layer formed by a plating method, but embodiments are not limited thereto. The c-th bonding pad 133c, the d-th bonding pad 133d, and the d-th bump 135d may form a c-th bonding structure BSc_1 for the c-th memory die 100c and the d-th memory die 100d. The c-th bonding structure BSc_1 may correspond to the a-th bonding structure BSa_1, and may be electrically connected to the plurality of c-th input/output pad 131c and the redistribution layer.

Through the symmetrical arrangement of the plurality of d-th bonding pads 133d according to channels within the d-th pad map region PMd and the symmetrical arrangement of the plurality of c-th bonding pads 133c according to channels within the c-th pad map region PMc, plurality of c-th bonding pads 133c and plurality of d-th bonding pads 133d, which correspond to one another, may be aligned in the third direction DR3 and electrically connected. Through the arrangement of the bonding pads within the pad map region, even if the d-th memory die 100d is rotated and flipped to be connected to the c-th memory die 100c, the corresponding plurality of c-th bonding pads 133c and the plurality of d-th bonding pads 133d may be connected to each other as a part of the c-th bonding structure BSc_1.

Signals input/output through the plurality of c-th input/output pads 131c may be bifurcated and input/output to the c-th memory die 100c and the d-th memory die 100d through the c-th bonding structure BSc_1, without bifurcating through a separate wire.

In some embodiments, each of the a-th to d-th memory dies 100a to 100d may operate as a single rank. According to some embodiments, each of the a-th to d-th memory dies 100a to 100d may receive a predetermined chip selection signal and may be individually activated in response to the chip selection signal.

The sealing member 160 may surround the sides of the a-th to d-th memory dies 100a to 100d. The sealing member 160 may cover at least a portion of the upper surfaces of the a-th to c-th memory dies 100a to 100c. The upper surface of the d-th memory die 100d, i.e., the eighth surface 112d, may be exposed by the sealing member 160. For example, the sealing member 160 may contain a thermosetting resin, etc.

The memory package 10_1 may include the a-th bonding structure BSa_1 and the c-th bonding structure BSc_1 between the same type of a-th to d-th memory dies 100a to 100d of the same type, through the arrangement of a plurality of a-th to d-th bonding pads 133a to 133d within the a-th to d-th pad map region PMa to PMd. The memory package 10_1 may load four a-th to d-th memory dies 100a to 100d into each of the zeroth to third channels CH0 to CH3 through the a-th bonding structure BSa_1 and the c-th bonding structure BSc_1 while reducing wire bifurcation. The memory package 10_1 may load four a-th to d-th memory dies 100a to 100d through two wires Wa and Wc.

That is, the memory package 10_1 can reduce the reflection at the wire pad WP and improve the signal quality, by reducing wire-bifurcation from the wire pad WP using the bonding structures WP.

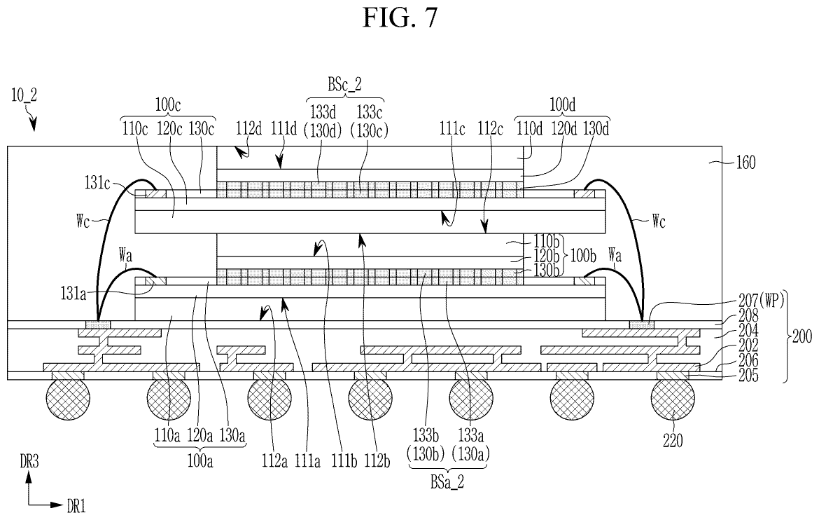

FIG. 7 is a cross-sectional view showing a memory package according to an embodiment. The memory package 10_2 of FIG. 7 may correspond to the memory package 10_1 of FIG. 1 to FIG. 6, and the a-th to d-th memory dies 100a to 100d of FIG. 7 may correspond to the a-th to d-th memory dies 100a to 100d of FIG. 1 to FIG. 6. For convenience of explanation, the memory package 10_2 will be described by focusing on the differences from the memory package 10_1 of FIG. 1 to FIG. 6.

Referring to FIG. 7, a plurality of a-th bonding pads 133a exposed by the a-th passivation film 139a of the a-th memory die 100a and a plurality of b-th bonding pads 133b exposed by the b-th passivation film 139b of the b-th memory die 100b may be directly bonded in a pad-to-pad fashion by a hybrid bonding method.

The plurality of a-th bonding pads 133a and the plurality of b-th bonding pads 133b may be in direct contact with each other without arrangement of bumps, and may form an a-th bonding structure BSa_2 together with the a-th passivation film 139a and the b-th passivation film 139b.

At least a portion of the a-th passivation film 139a may overlap with the b-th passivation film 139b in the third direction DR3. The a-th passivation film 139a and the b-th passivation film 139b may contact each other. The a-th passivation film 139a and the b-th passivation film 139b may be bonded to each other by a high temperature annealing process in a state of mutual contact, and may have a strong bonding strength as a part of the bonding structure.

A plurality of c-th bonding pads 133c of the c-th memory die 100c and a plurality of d-th bonding pads 133d of the d-th memory die 100d may be directly bonded in a pad-to-pad fashion by a hybrid bonding method.

The plurality of c-th bonding pads 133c and the plurality of d-th bonding pads 133d may be in direct contact with each other without arrangement of bumps, and may form a c-th bonding structure BSc_2 together with the a-th passivation film 139a and the b-th passivation film 139b.

At least a portion of the passivation film in c-th pad layer 130c may overlap with the passivation film in the d-th pad layer 130d in the third direction DR3. The passivation film in the c-th pad layer 130c and the passivation film in the d-th pad layer 130d may contact each other. The passivation film in the c-th pad layer 130c and the passivation film in the d-th pad layer 130d may be bonded to each other by a high temperature annealing process in a state of mutual contact, and may have a strong bonding strength as a part of the bonding structure.

The memory package 10_2 may load four a-th to d-th memory dies 100a to 100d into each of a plurality of channels through the a-th bonding structure BSa_2 and the c-th bonding structure BSc_2 while reducing wire bifurcation. The memory package 10_2 may load four a-th to d-th memory dies 100a to 100d through two wires Wa and Wc.

That is, the memory package 10_2 can reduce the reflection at the wire pad WP and improve the signal quality, by reducing wire-bifurcation from the wire pad WP using the bonding structures.

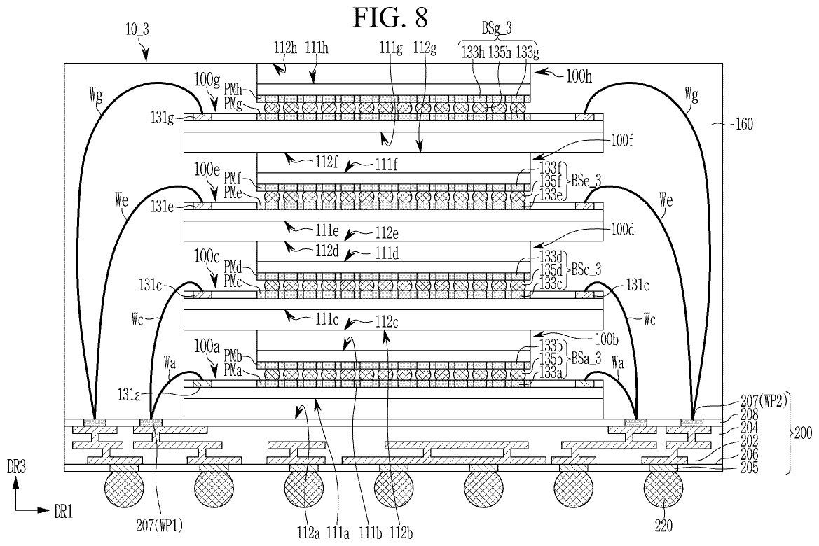

FIG. 8 is a cross-sectional view showing a memory package according to an embodiment. The memory package 10_3 of FIG. 8 may correspond to the memory package 10_1 of FIG. 1 to FIG. 6. The package substrate 200 of FIG. 8 may correspond to the package substrate 200 of FIG. 1 to FIG. 6, and the a-th to d-th memory dies 100a to 100d of FIG. 7 may correspond to the a-th to d-th memory dies 100a to 100d of FIG. 1 to FIG. 6. For convenience of explanation, the memory package 10_3 will be described by focusing on the differences from the memory package 10_1 of FIG. 1 to FIG. 6.

Referring to FIG. 8, the memory package 10_3 may include a memory stacking structure including a-th to d-th memory dies 100a to 100d stacked in a third direction DR3, e-th to h-th memory dies 100e to 100h stacked in the third direction DR3 on the a-th to d-th memory dies 100a to 100d, and a package substrate 200 on which the memory stacking structure is mounted.

The package substrate 200 may correspond to the package substrate 200 of FIG. 1 to FIG. 6. For convenience of explanation, the package substrate 200 will be described by focusing on the differences from the package substrate 200 of FIG. 1 to FIG. 6.

The at least one substrate pad 207, which is arranged in the package substrate 200, may include a first wire pad WP1 and a second wire pad WP2. The first wire pad WP1 may be electrically connected to the a-th to d-th memory dies 100a to 100d through bifurcated wires Wa and Wc. The first wire pad WP1 may input/output signals for a plurality of channels, which are input/output from at least one external connection terminal 220, to the a-th to d-th memory dies 100a to 100d. In some embodiments, the first wire pad WP1 may input/output a signal for the zeroth to third channel, which are input/output from at least one external connection terminal 220, to the a-th to d-th memory dies 100a to 100d. Among the signals for the channels, a data signal may be input and output through the first wire pad WP1, and among the signals for the channel, a command address signal may be input through the first wire pad WP1.

The second wire pad WP2 may be electrically connected to the e-th to h-th memory dies 100e to 100h through bifurcated wires We and Wg. The second wire pad WP2 may input/output signals for a plurality of channels, which are input/output from at least one external connection terminal 220, to the e-th to h-th memory dies 100e to 100h. In some embodiments, the second wire pad WP2 may input/output a signal for the fourth to seventh channel, which are input/output from at least one external connection terminal 220, to the e-th to h-th memory dies 100e to 100h. Among the signals for the channels, a data signal may be input and output through the second wire pad WP2, and among the signals for the channel, a command address signal may be input through the second wire pad WP2.

The a-th memory die 100a may correspond to the a-th memory die 100a of FIG. 1 to FIG. 6. For convenience of explanation, the c-th memory die 100c will be described by focusing on the differences from a-th memory die 100a of FIG. 1 to FIG. 6.

A plurality of c-th input/output pad 131c may be electrically connected to the first wire pad WP1 via a c-th wire Wc. In some embodiments, a plurality of c-th input/output pads 131c may input/output signals of the zeroth to third channels input and output from the first wire pads WP1 to the c-th memory die 100c and the d-th memory die 100d. Among the signals for the channel, a data signal may be input/output through the plurality of c-th input/output pads 131c, and a command address signal may be input through the plurality of c-th input/output pads 131c.

The d-th memory die 100d may correspond to the d-th memory die 100d of FIG. 1 to FIG. 6. The c-th bonding pad 133c of the c-th memory die 100c and the d-th bonding pad 133d of the d-th memory die 100d may be bonded via the d-th bump 135d, and the c-th bonding pad 133c, the d-th bonding pad 133d, and the d-th bump 135d may form a c-th bonding structure BSc_3 for the c-th memory die 100c and the d-th memory die 100d.

The e-th memory die 100e may include an e-th substrate, an e-th wiring layer, and an e-th pad layer sequentially stacked in third direction DR3. The f-th memory die 100f may include an f-th substrate, an f-th wiring layer, and an f-th pad layer, which may be stacked in a direction opposite to the third direction DR3. Each of the e-th memory die 100e and the f-th memory die 100f may correspond to each of the a-th memory die 100a and the b-th memory die 100b.

The e-th substrate may have a ninth surface 111e and a tenth surface 112e which are opposite to each other. The ninth surface 111e may be an active surface and may face the f-th memory die 100f. The tenth surface 112e may be an inactive surface and may face the d-th memory die 100d. As an active surface of the e-th substrate 110e, memory elements or circuit elements may be disposed on the ninth surface 111e of the e-th substrate 110e. The ninth surface 111e may be referred to as a front surface where the memory elements or circuit elements are disposed, and the tenth surface 112e may be referred to as a rear surface.

The e-th wiring layer may be disposed on the ninth surface 111e, and the e-th pad layer may be disposed on the e-th wiring layer. The e-th pad layer 130e may include a plurality of e-th input/output pad 131e, a plurality of e-th bonding pad 133e, a redistribution layer connecting the plurality of e-th input/output pads 131e and the plurality of e-th bonding pads 133e, and a passivation film exposing portions of the plurality of e-th input/output pads 131e and the plurality of e-th bonding pads 133e.

A plurality of e-th bonding pads 133e may be arranged in a e-th pad map region PMe, which includes a center of the ninth surface 111e, within the e-th pad layer 130e. A plurality of e-th input/output pads 131e may be arranged in a non-overlapping manner with the e-th pad map region PMe in the e-th pad layer 130e.

The e-th pad map region PMe may overlap with an f-th pad map region PMf of the opposing f-th memory die 100f, in a plan view. A plurality of e-th input/output pads 131e may be arranged on the e-th wiring layer 120e so as not to overlap f-th memory die 100f in a plan view.

A plurality of e-th input/output pads 131e may be electrically connected to at least one second wire pad WP2 via at least one e-th wire We. In some embodiments, a plurality of e-th input/output pads 131e may input/output signals of the fourth to seventh channels, which are input and output from the second wire pads WP2, to the e-th memory die 100e and the f-th memory die 100f. Among the signals for the channel, a data signal may be input/output through the plurality of e-th input/output pads 131e, and a command address signal may be input through the plurality of e-th input/output pads 131e.

A plurality of e-th bonding pads 133e may input/output signals for the fourth to seventh channel, which are input/output from the plurality of e-th input/output pads 131e, to the e-th memory die 100e and the f-th memory die 100f.

The plurality of e-th bonding pads 133e may be arranged at specific positions in the e-th pad map region PMe depending on input/output signals, such as the arrangement of the plurality of a-th bonding pads 133a in the a-th pad map region PMa. Two of the e-th bonding pads 133e, which are mirrored according to different channels and input/output the same type of signal, may be arranged in a point symmetry with respect to a center in the e-th pad map region PMe. Also, two of the e-th bonding pads 133e, which are mirrored according to different channels and input/output the same type of signal, may be symmetrically arranged with respect to the first diagonal direction DR4 or the second diagonal direction DR5 in the e-th pad map region PMe. The same type of signal may be defined as signals that are the same at the netlist level.

The f-th substrate 110f may have an eleventh surface 111f and a twelfth surface 112f which are opposed to each other. The eleventh surface 111f may be an active surface and may face the e-th memory die 100e. The twelfth surface 112f may be an inactive surface and may face the g-th memory die 100g. As an active surface of the f-th substrate, memory elements or circuit elements may be disposed on the eleventh surface 111f of the f-th substrate 110f. The eleventh surface 111f may be referred to as a front surface where the memory elements or circuit elements are disposed, and the twelfth surface 112f may be referred to as a rear surface.

The f-th first wiring layer 120f may be disposed on the eleventh surface 111f and the f-th pad layer 130f may be disposed on the f-th wiring layer 120f. The f-th pad layer 130d may include a plurality of f-th bonding pads 133f and a passivation film exposing portions of the plurality of f-th bonding pads 133f.

A plurality of f-th bonding pads 133f may be disposed at an f-th pad map region PMf, which includes a center of the eleventh surface 111f, within the f-th pad layer 130f. The f-th pad map region PMf may overlap with the e-th pad map region PMe of the opposing e-th memory die 100e, in a plan view.

A plurality of f-th bonding pads 133f may be disposed at specific positions in the f-th pad map region PMf depending on input/output signals, such as the arrangement of the plurality of b-th bonding pads 133b in the b-th pad map region PMb. Two of the f-th bonding pads 133f, which are mirrored according to different channels and input/output the same type of signal, may be arranged in a point symmetry with respect to a center in the f-th pad map region PMf. Also, two of the f-th bonding pads 133f, which are mirrored according to different channels and input/output the same type of signal, may be symmetrically arranged with respect to the first diagonal direction DR4 or the second diagonal direction DR5 in the f-th pad map region PMf. The same type of signal may be defined as signals that are the same at the netlist level.

The f-th bonding pad 133f and the e-th bonding pad 133e, which input/output the same type of signal for the same channel, may be aligned in the third direction DR3 so that they can overlap in a plan view.

The e-th bonding pad 133e and the f-th bonding pad 133f, which are aligned in the third direction DR3 to overlap with each other in a plan view, may be electrically connected to each other, and the e-th bonding pad 133e and the f-th bonding pad 133f, which are aligned in the third direction D3 and overlap in a plan view, may be bonded through the f-th bump 135f. The f-th bump 135f may be a micro bump including a metal layer formed by a plating method, but embodiments are not limited thereto. The e-th bonding pad 133e, the f-th bonding pad 133f, and the f-th bump 135f may form an e-th bonding structure BSe_3 for the e-th and f-th memory dies 100e and 100f. The e-th bonding structure BSe_3 may correspond to the a-th bonding structure BSa_1, and may be electrically connected to the plurality of e-th input/output pad 131e and the redistribution layer.

Through the symmetrical arrangement of the plurality of f-th bonding pads 133f according to channels within the f-th pad map region PMf and the symmetrical arrangement of the plurality of e-th bonding pads 133e according to channels within the e-th pad map region PMe, plurality of e-th bonding pads 133e and plurality of f-th bonding pads 133f, which correspond to one another, may be aligned in the third direction DR3 and electrically connected. Through the arrangement of the bonding pads within the pad map region, even if the f-th memory die 100f is rotated and flipped to be connected to the e-th memory die 100e, the corresponding plurality of e-th bonding pads 133e and the plurality of f-th bonding pads 133f may be connected to each other as a part of the e-th bonding structure BSe_3.

Signals input/output through the plurality of e-th input/output pads 131e may be bifurcated and input/output to the e-th memory die 100e and the f-th memory die 100f through the e-th bonding structure BSe_3, without bifurcating through a separate wire.

The g-th memory die 100g may include a g-th substrate, a g-th wiring layer, and a g-th pad layer sequentially stacked in third direction DR3. The h-th memory die 100h may include an h-th substrate, an h-th wiring layer, and an h-th pad layer, which may be stacked in a direction opposite to the third direction DR3. Each of the g-th memory die 100g and the h-th memory die 100h may correspond to each of the c-th memory die 100c and the d-th memory die 100d.

The g-th substrate 110g may have a thirteenth surface 111g and a fourteenth surface 112g which are opposed to each other. The thirteenth surface 111g may be an active surface and may face the h-th memory die 100h. The fourteenth surface 112g may be an inactive surface and may face the f-th memory die 100f. As an active surface of the g-th substrate 110g, memory elements or circuit elements may be disposed on the thirteenth surface 111g of the g-th substrate 110g. The thirteenth surface 111g may be referred to as a front surface where the memory elements or circuit elements are disposed, and the fourteenth surface 112g may be referred to as a rear surface.

The g-th first wiring layer 120g may be disposed on the thirteenth surface 111g and the g-th pad layer 130g may be disposed on the g-th wiring layer 120g. The g-th pad layer 130g may include a plurality of g-th input/output pad 131g, a plurality of g-th bonding pad 133g, a redistribution layer connecting th plurality of g-th input/output pad 131g and the plurality of g-th bonding pad 133g, and a passivation film exposing portions of the plurality of g-th input/output pad 131g and the plurality of g-th bonding pad 133g.

A plurality of g-th bonding pads 133g may be disposed at a g-th pad map region PMg, which includes a center of the thirteenth surface 111g, within the g-th pad layer 130g. A plurality of g-th input/output pads 131g may be arranged in a non-overlapping manner with the g-th pad map region PMg in the g-th pad layer 130g.

The g-th pad map region PMg may overlap with an h-th pad map region PMh of the opposing h-th memory die 100h, in a plan view. A plurality of g-th input/output pads 131g may be arranged on the g-th wiring layer 120g so as not to overlap h-th memory die 100h in a plan view.

A plurality of g-th input/output pad 131g may be electrically connected to the second wire pad WP2 via a g-th wire Wg. In some embodiments, a plurality of g-th input/output pads 131g may input/output signals of the fourth to seventh channels input and output from the second wire pad WP2 to the g-th and h-th memory dies 100g and 100h. Among the signals for the channel, a data signal may be input/output through the plurality of g-th input/output pads 131g, and a command address signal may be input through the plurality of g-th input/output pads 131g.

A plurality of g-th bonding pad 133g may input/output signals for the zeroth to seventh channel, which are input/output from the plurality of g-th input/output pad 131g, to the g-th and h-th memory dies 100g and 100h.

A plurality of g-th bonding pads 133g may be disposed at specific positions in the g-th pad map region PMg depending on input/output signals, such as the arrangement of the plurality of c-th bonding pads 133c in the c-th pad map region PMc. Two of the g-th bonding pads 133g, which are mirrored according to different channels and input/output the same type of signal, may be arranged in a point symmetry with respect to a center in the g-th pad map region PMg. Also, two of the g-th bonding pads 133g, which are mirrored according to different channels and input/output the same type of signal, may be symmetrically arranged with respect to the first diagonal direction DR4 or the second diagonal direction DR5 in the g-th pad map region PMg. The same type of signal may be defined as the signals same at the netlist level.

The h-th substrate 110h may have a fifteenth surface 111h and a sixteenth surface 112h which are opposed to each other. The fifteenth surface 111h is an active surface and may face the g-th memory die 100g, and the sixteenth surface 112h is an inactive surface. As an active surface of the h-th substrate 110h, memory elements or circuit elements may be disposed on the fifteenth surface 111h of the h-th substrate 110h. The fifteenth surface 111h may be referred to as a front surface where the memory elements or circuit elements are disposed, and the sixteenth surface 112h may be referred to as a rear surface.

The h-th first wiring layer 120h may be disposed on the fifteenth surface 111h and the h-th pad layer 130h may be disposed on the h-th wiring layer 120h. The h-th pad layer 130h may include a plurality of h-th bonding pads 133h and a passivation film exposing portions of the plurality of h-th bonding pads 133h.

A plurality of h-th bonding pads 133h may be disposed at the h-th pad map region PMh, which includes a center of the fifteenth surface 111h, within the h-th pad layer 130h. The h-th pad map region PMh may overlap with the g-th pad map region PMg of the opposing g-th memory die 100g, in a plan view.

A plurality of h-th bonding pads 133h may be disposed at specific positions in the h-th pad map region PMh depending on input/output signals, such as the arrangement of the plurality of d-th bonding pads 133d in the d-th pad map region PMd. Two of the h-th bonding pads 133h, which are mirrored according to different channels and input/output the same type of signal, may be arranged in a point symmetry with respect to a center in the h-th pad map region PMh. Also, two of the h-th bonding pads 133h, which are mirrored according to different channels and input/output the same type of signal, may be symmetrically arranged with respect to the first diagonal direction DR4 or the second diagonal direction DR5 in the h-th pad map region PMh. The same type of signal may be defined as signals that are the same at the netlist level.

The h-th bonding pad 133h and the g-th bonding pad 133g, which input/output the same type of signal for the same channel, may be aligned in the third direction DR3 so that they can overlap in a plan view.

The g-th bonding pad 133g and the h-th bonding pad 133h, which are aligned in the third direction DR3 to overlap with each other in a plan view, may be electrically connected to each other, and the g-th bonding pad 133g and the h-th bonding pad 133h, which are aligned in the third direction D3 and overlap in a plan view, may be bonded through the h-th bump 135h. The h-th bump 135h may be a micro bump including a metal layer formed by a plating method, but embodiments are not limited thereto. The g-th bonding pad 133g, the h-th bonding pad 133h, and the h-th bump 135h may form a g-th bonding structure BSg_3 for the g-th and h-th memory dies 100g and 100h. The g-th bonding structure BSg_3 may correspond to the c-th bonding structure BSc_3, and may be electrically connected to the plurality of g-th input/output pad 131g and the redistribution layer.

Through the symmetrical arrangement of the plurality of h-th bonding pads 133h according to channels within the h-th pad map region PMh and the symmetrical arrangement of the plurality of g-th bonding pads 133g according to channels within the g-th pad map region PMg, plurality of g-th bonding pads 133g and plurality of h-th bonding pads 133h, which correspond to one another, may be aligned in the third direction DR3 and electrically connected. Through the arrangement of the bonding pads within the pad map region, even if the h-th memory die 100h is rotated and flipped to be connected to the g-th memory die 100g, the corresponding plurality of g-th bonding pads 133g and the plurality of h-th bonding pads 133h may be connected to each other as a part of the g-th bonding structure BSg_3.

Signals input/output through the plurality of g-th input/output pads 131g may be bifurcated and input/output to the g-th memory die 100g and the h-th memory die 100h through the g-th bonding structure BSg_3, without bifurcating through a separate wire.

In some embodiments, each of the e-th to h-th memory dies 100e to 100h may operate as a single rank. According to some embodiments, each of the e-th to h-th memory dies 100e to 100h receives a predetermined chip selection signal and may be individually activated in response to the chip selection signal.

The memory package 10_3 may load four a-th to d-th memory dies 100a to 100d into each of the zeroth to third channels through the a-th bonding structure BSa_3 and the c-th bonding structure BSc_3 while reducing wire bifurcation. The memory package 10_3 may load four a-th to d-th memory dies 100a to 100d through two wires Wa and Wc. Also, the memory package 10_3 may load four e-th to h-th memory dies 100e to 100h into each of a plurality of channels through the e-th bonding structure BSe_3 and the g-th bonding structure BSg_3 while reducing wire bifurcation. The memory package 10_3 may load four e-th to h-th memory dies 100e to 100h through two wires We and Wg.

That is, the memory package 10_3 can reduce the reflection at the wire pads WP1 and WP2 and improve the signal quality, by reducing wire-bifurcation from the wire pads WP1 and WP2 using the bonding structures.

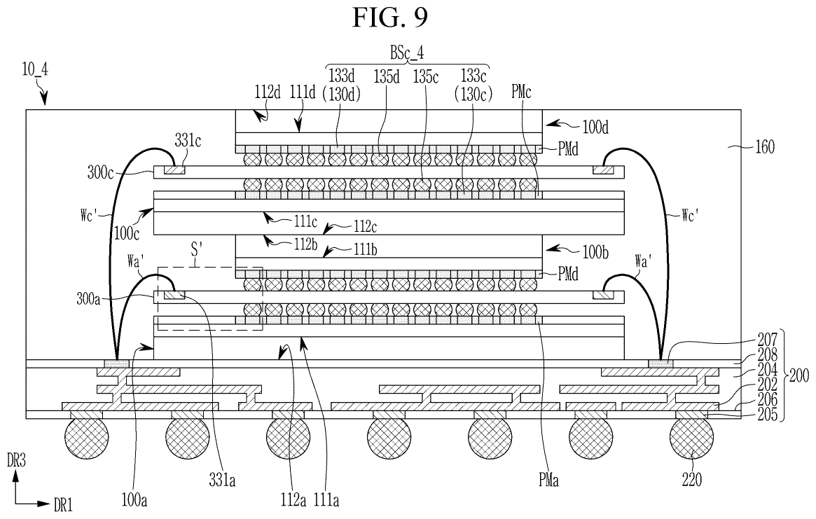

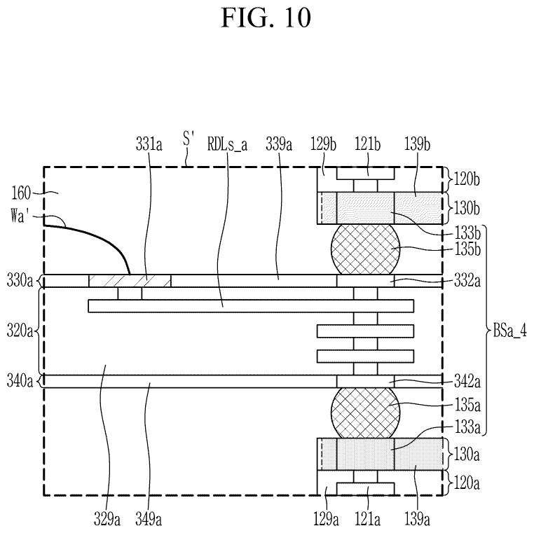

FIG. 9 is a cross-sectional view showing a memory package according to an embodiment. FIG. 10 is an enlarged view of a region S′ of FIG. 9. The memory package 10_4 of FIG. 9 and FIG. 10 may correspond to the memory package 10_1 of FIG. 1 to FIG. 6, and the a-th to d-th memory dies 100a to 100d of FIG. 9 and FIG. 10 may correspond to the a-th to d-th memory dies 100a to 100d of FIG. 1 to FIG. 6. For convenience of explanation, the memory package 10_4 will be described by focusing on the differences from the memory package 10_1 of FIG. 1 to FIG. 6.

Referring to FIG. 9 and FIG. 10, the memory package 10_4 may further include an a-th interposer 300a interposed between the a-th memory die 100a and the b-th memory die 100b, and a c-th interposer 300c interposed between the c-th memory die 100c and the d-th memory die 100d.

The a-th interposer 300a may electrically connect a-th memory dies 100a and b-th memory dies 100b, and c-th interposer 300c may electrically connect c-th memory dies 100c and d-th memory dies 100d. The a-th interposer 300a and the c-th interposer 300c may be organic substrates, interposer substrates, and the like. Additionally, In some embodiments, the a-th interposer 300a and the c-th interposer 300c may be manufactured based on an active wafer such as a silicon wafer.

The a-th interposer 300a may include an a-th redistribution layer 320a, an a-th upper pad layer 330a, and an a-th lower pad layer 340a.

The a-th redistribution layer 320a may include a-th redistribution structure RDLs_a and a-th redistribution insulation layer 329a including the a-th redistribution structure RDLs_a.

The a-th redistribution structure RDLs_a may correspond to the a-th redistribution layer RDL_a of FIG. 1 to FIG. 6. The a-th redistribution structure RDLs_a may electrically connect a plurality of a-th input/output pads 331a and a plurality of a-th upper pads 332a, which are disposed at the a-th upper pad layer 330a, to a plurality of a-th lower pads 342a disposed at the a-th lower pad layer 340a. The a-th redistribution structure RDLs_a may include a plurality of wiring lines vertically stacked from the a-th redistribution insulation layer 329a in the third direction DR3, and a plurality of vias connecting the stacked plurality of wiring lines.

The a-th upper pad layer 330a may include a plurality of a-th input/output pads 331a, a plurality of a-th upper pads 332a, and a-th upper passivation film 339a. At least a portion of a plurality of a-th input/output pads 331a and a plurality of a-th upper pads 332a may be exposed by the a-th upper passivation film 139a.

The plurality of a-th input/output pad 331a may correspond to the plurality of a-th input/output pad 131a of FIG. 1 to FIG. 6. A plurality of a-th input/output pad 331a may be electrically connected to the wire pad WP via an a-th wire Wa′

In some embodiments, a plurality of a-th input/output pads 131a may input/output signals of the zeroth to third channels, which are input and output from at least one wire pad WP, to the a-th memory die 100a and the b-th memory die 100b. Among the signals for the channel, a data signal may be input/output through the plurality of a-th input/output pads 331a, and a command address signal may be input through the plurality of a-th input/output pads 331a.

The plurality of a-th upper pad 332a may be disposed on the upper surface of the a-th redistribution structure RDLs_a, and may be connected to the plurality of b-th bonding pad 133b through the b-th bump 135b. The b-th bump 135b may be a micro bump including a metal layer formed by a plating method, but embodiments are not limited thereto. A plurality of a-th upper pads 332a may input/output signals for the zeroth to third channel, which are input/output from the plurality of a-th input/output pads 331a, to the b-th memory die 100b.

The a-th lower pad layer 340a may include the a-th lower pad 342a and the a-th lower passivation film 349a exposing a portion of the a-th lower pad 342a. The a-th lower pad 342a may be disposed under the a-th redistribution structure RDLs_a, and may be bonded with the plurality of a-th bonding pads 133a via the a-th bump 135a. The a-th bump 135a may be a micro bump including a metal layer formed by a plating method, but embodiments are not limited thereto. The a-th lower pad 342a may input/output signals for the zeroth to third channels, which are input/output from a plurality of a-th input/output pads 331a, to the a-th memory die 100a.

The a-th bonding pad 133a, the a-th bump 135a, the b-th bonding pad 133b, and the b-th bump 135b may form an a-th bonding structure BSa_4 for the a-th memory die 100a and the b-th memory die 100b together with the a-th upper pad 332a and the a-th lower pad 342a of the a-th interposer 300a. The a-th bonding structure BSa_4 may be electrically connected to a plurality of a-th input/output pads 331a and the a-th redistribution structure RDLs_a.

The c-th interposer 300c may correspond to the a-th interposer 300a, and may include a c-th redistribution layer, a c-th upper pad layer, and a c-th lower pad layer.

The plurality of c-th input/output pads 331c disposed on the c-th upper pad layer may correspond to the plurality of c-th input/output pads 131c of FIG. 1 to FIG. 6. A plurality of c-th input/output pads 331c may be electrically connected to the wire pad WP via at least one c-th wire Wc′. In some embodiments, a plurality of c-th input/output pads 331c may input/output signals of the zeroth to third channels, which are input and output from the wire pad WP, to the c-th memory die 100d and the d-th memory die 100d. Among the signals for the channel, a data signal may be input/output through the plurality of c-th input/output pads 331c, and a command address signal may be input through the plurality of c-th input/output pads 331c.

A plurality of upper pads disposed on the c-th upper pad layer may input/output signals for the zeroth to third channels, which are input/output from the plurality of c-th input/output pads 331c, to the d-th memory die 100d. The plurality of lower pads disposed at the c-th lower pad layer may input/output signals for the zeroth to third channels, which are input/output from the plurality of c-th input/output pads 331c, to the c-th memory die 100c.

The c-th bonding pad 133c, the c-th bump 135c, the d-th bonding pad 133d, and the d-th bump 135d may form a c-th bonding structure BSc_4 for the c-th memory die 100c and the d-th memory die 100d together with the plurality of upper and lower pads of the c-th interposer 300c. The c-th bonding structure BSc_4 may be electrically connected to the plurality of c-th input/output pads 331c and the redistribution structure in the c-th interposer 300c.

The memory package 10_4 may load four a-th to d-th memory dies 100a to 100d into each of a plurality of channels through the a-th bonding structure BSa_4 and the c-th bonding structure BSc_4 while reducing wire bifurcation. The memory package 10_4 may load four a-th to d-th memory dies 100a to 100d through two wires Wa and Wc.

That is, the memory package 10_4 can reduce the reflection at the wire pad WP and improve the signal quality, by reducing wire-bifurcation from the wire pad WP using the bonding structures.

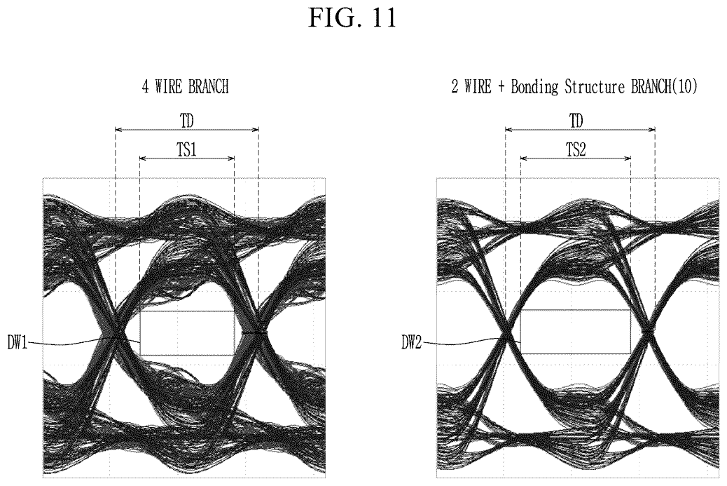

FIG. 11 illustrates an eye pattern for input/output signals within a memory die according to an embodiment. Specifically, FIG. 11 illustrates an eye pattern for a data signal bifurcated from a wire pad through four wires, and an eye pattern for a data signal bifurcated through wires and bonding structures according to an embodiment.

When bifurcated through four wires from a wire pad, other wires may act as stubs to cause reflections, and the reflections may cause distortion in the signals input/output from other wires. Depending on signal distortion, the timing margin for data sampling may be reduced.

The memory package 10 according to an embodiment can improve reflection and signal distortion occurring at the wire pads, by reducing bifurcations from a wire pad using the bonding structure.

A second data sampling width TS2 of the data signal bifurcated from the memory package 10 may be wider than A first data sampling width TS1 of the data signal bifurcated through four wires.

In the memory package 10, a second data window DW2 of the data signal bifurcated through the bonding structure may have a wider range than a first data window DW1 of the data signal bifurcated through the four wires.

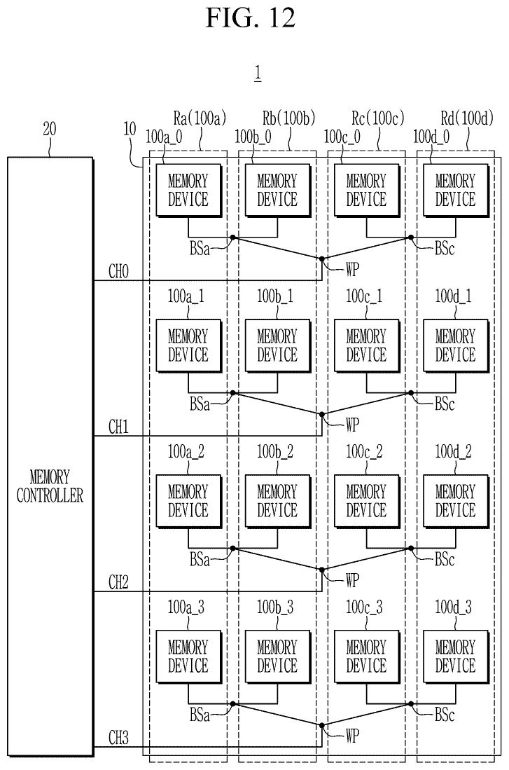

FIG. 12 is a block diagram of a memory system according to an embodiment.

Referring to FIG. 12, a memory system 1 may include a memory package 10 and a memory controller 20.

The memory controller 20 may act as an interface between a processor and the memory devices 100a_0 to 100d_3 in the memory package 10, and may manage and control access to the memory devices 100a_0 to 100d_3. In some embodiments, the memory controller 20 may include a processor.

The memory controller 20 may write or read data to and from the memory devices in the memory package 10 through a plurality of channels CH0 to CH3. The memory controller 20 may independently provide command address signals to the memory device and input/output data signals according to a plurality of channels (e.g., a zeroth channel CH0, a first channel CH1, a second channel CH2, and a third channel CH3).

The memory package 10 may include a_0-th to d_3-th memory devices 100a_0 to 100d_3. The memory controller 20 may input/output data signals for the a_0-th to d_0-th memory devices 100a_0 to 100d_0 through the zeroth channel CH0, and the data signals may be bifurcated into four signals through the wire pad WP and bonding structures BSa and BSc. The memory controller 20 may input/output data signals for the a_1-th to d_1-th memory devices 100a_1 to 100d_1 through the first channel CH1, and the data signals may be bifurcated into four signals through wire pad WP and bonding structures BSa and BSc. The memory controller 20 may input/output data signals for the a_2-th to d_2-th memory devices 100a_2 to 100d_2 through the second channel CH2, and the data signals may be bifurcated into four signals through the wire pad WP and bonding structures BSa and BSc. The memory controller 20 may input/output data signals for the a_3-th to d_3-th memory devices 100a_3 to 100d_3 through the third channel CH3, and the data signals may be bifurcated into four signals through wire pad WP and bonding structures BSa and BSc.

The memory package 10 can improve the quality of input/output signals while loading a plurality of memory devices into the channels, by bifurcating signals, which are input/output through channels, through a bonding structure as shown in FIG. 1 to FIG. 11.

The memory package 10 may perform four-rank operations. The a_0-th to a_3-th memory devices 100a_0 to 100a_3 may operate as a a-th rank Ra, and may be activated by a predetermined chip selection signal. The a-th rank Ra may correspond to the a-th memory die 100a in FIG. 1 to FIG. 11. The b_0-th to b_3-th memory devices 100b_0 to 100b_3 may operate as a b-th rank Rb, and may be activated by a predetermined chip selection signal. The b-th rank Rb may correspond to the b-th memory die 100b in FIG. 1 to FIG. 11. The c_0-th to c_3-th memory devices 100c_0 to 100c_3 may operate as a c-th rank Rc, and may be activated by a predetermined chip selection signal. The c-th rank Rc may correspond to the c-th memory die 100c in FIG. 1 to FIG. 11. The d_0-th to d_3-th memory devices 100d_0 to 100d_3 may operate as a d-th rank Rd, and may be activated by a predetermined chip selection signal. The d-th rank Rd may correspond to the d-th memory die 100d in FIG. 1 to FIG. 11.

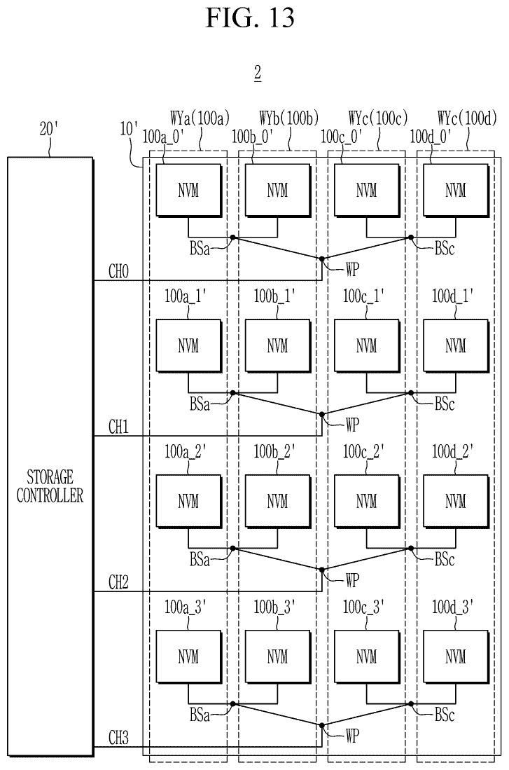

FIG. 13 is a block diagram of a storage system according to an embodiment.

Referring to FIG. 13, a storage system 2 may include a memory package 10′ and a storage controller 20′.

The storage controller 20′ may act as an interface between the host and non-volatile memory devices 100a_0′ to 100d_3′ in the memory package 10′, may control operations of the non-volatile memory devices 100a_0′ to 100d_3′, and may manage mapping information for the non-volatile memory devices 100a_0′ to 100d_3′.

The storage controller 20′ may write or read data to and from the non-volatile memory devices in the memory package 10′ through a plurality of channels (e.g., a zeroth channel CH0, a first channel CH1, a second channel CH2, and a third channel CH3). The storage controller 20′ may independently provide command address signals to the non-volatile memory device and input/output data signals according to the plurality of channels (e.g., the zeroth channel CH0, the first channel CH1, the second channel CH2, and the third channel CH3).

The memory package 10′ may include a_0-th to d_3-th non-volatile memory devices 100a_0′ to 100d_3′. The storage controller 20′ may input/output data signals for the a_0-th to d_0-th non-volatile memory devices 100a_0′ to 100d_0′ through the zeroth channel CH0, and the data signals may be bifurcated into four signals through wire pad WP and bonding structures BSa and BSc. The storage controller 20′ may input/output data signals for the a_1-th to d_1-th non-volatile memory devices 100a_1 to 100d_1 through the first channel CH1, and the data signals may be bifurcated into four signals through the wire pad WP and bonding structures BSa and BSc. The storage controller 20′ may input/output data signals for the a_2-th to d_2-th non-volatile memory devices 100a_2′ to 100d_2′ through the second channel CH2, and the data signals may be bifurcated into four signals through wire pad WP and bonding structures BSa and BSc. The storage controller 20′ may input/output data signals for the a_3-th to d_3-th non-volatile memory devices 100a_3′ to 100d_3′ through the third channel CH3, and the data signals may be bifurcated into four signals through the wire pad WP and bonding structures BSa and BSc.

The memory package 10 can improve the quality of input/output signals while loading a plurality of non-volatile memory devices into the channels, by bifurcating signals, which are input/output through channels, through a bonding structure as shown in FIG. 1 to FIG. 11.

The memory package 10′ may perform four-way operations. The a_0-th to a_3-th non-volatile memory devices 100a_0′ to 100a_3′ may operate as a a-th way WYa, and may be activated by a predetermined chip selection signal. The a-th way WYa may correspond to the a-th memory die 100a in FIG. 1 to FIG. 11. The b_0-th to b_3-th non-volatile memory devices 100b_0′ to 100b_3′ may operate as a b-th way WYb, and may be activated by a predetermined chip selection signal. The b-th way WYb may correspond to the b-th memory die 100b in FIG. 1 to FIG. 11. The c_0-th to c_3-th non-volatile memory devices 100c_0′ to 100c_3′ may operate as a c-th way WYc, and may be activated by a predetermined chip selection signal. The c-th way WYc may correspond to the c-th memory die 100c in FIG. 1 to FIG. 11. The d_0-th to d_3-th non-volatile memory devices 100d_0′ to 100d_3) may operate as a d-th way WYd, and may be activated by a predetermined chip selection signal. The d-th way WYd may correspond to the d-th memory die 100d in FIG. 1 to FIG. 11.

Although non-limiting example embodiments of the present disclosure have been described in detail above with reference to the accompanying drawings, the scope of the present disclosure is not limited thereto, and various modifications and improvements can be made by those skilled in the art, and such modifications and improvements are within the scope of the present disclosure.

What is claimed is:

1. A memory package comprising:
a first memory die comprising:
a first substrate;
a first wiring layer on a first surface of the first substrate, the first surface being a first active surface; and
a first bonding pad on the first wiring layer;
a second memory die comprising:
a second substrate on the first memory die;
a second wiring layer between the first surface of the first substrate and a second surface of the second substrate, the second surface being a second active surface; and
a second bonding pad on the second wiring layer and electrically connected to the first bonding pad; and
a package substrate comprising a first wire pad electrically connected, by a first wire, to the first bonding pad and the second bonding pad.

2. The memory package of claim 1, further comprising:
a third memory die comprising:
a third substrate;
a third wiring layer on a third surface of the third substrate, the third surface being a third active surface; and
a third bonding pad on the third wiring layer; and
a fourth memory die comprising:
a fourth substrate on the third memory die;
a fourth wiring layer between the third surface of the third substrate and a fourth surface of the fourth substrate, the fourth surface being a fourth active surface; and
a fourth bonding pad on the fourth wiring layer and electrically connected to the third bonding pad,
wherein the first wire pad is electrically connected, by a second wire, to the third bonding pad and the fourth bonding pad.

3. The memory package of claim 2, further comprising:
a fifth memory die comprising:
a fifth substrate;
a fifth wiring layer on a fifth surface of the fifth substrate, the fifth surface being a fifth active surface; and
a fifth bonding pad on the fifth wiring layer;
a sixth memory die comprising:
a sixth substrate on the fifth memory die;
a sixth wiring layer between the fifth surface and a sixth surface of the sixth substrate, the sixth surface being a sixth active surface; and
a sixth bonding pad on the sixth wiring layer and electrically connected to the fifth bonding pad;
a seventh memory die comprising:
a seventh substrate;
a seventh wiring layer on a seventh surface of the seventh substrate, the seventh surface being a seventh active surface; and
a seventh bonding pad on the seventh wiring layer; and
an eighth memory die comprising:
an eighth substrate on the seventh memory die;
an eighth wiring layer between the seventh surface of the seventh substrate and an eighth surface the eighth substrate, the eighth surface being which an eighth active surface; and
an eighth bonding pad on the eighth wiring layer and electrically connected to the seventh bonding pad,
wherein the package substrate further comprises a second wire pad electrically connected, by a third wire, to the fifth bonding pad and the sixth bonding pad, and connected, by a fourth wire, to the seventh bonding pad and the eighth bonding pad.

4. The memory package of claim 1, wherein the first memory die further comprises:
an input/output pad on the first wiring layer and connected to the first wire; and
a first redistribution layer extending on the first wiring layer and electrically connecting the first wire and the first bonding pad.

5. The memory package of claim 4, wherein
the first bonding pad is in a first pad map region of the memory package, the first pad map region overlapping with a center of the first surface in a plan view of the memory package; and
the input/output pad does not overlap with the first pad map region.

6. The memory package of claim 5, wherein
the input/output pad does not overlap with the second memory die in the plan view.

7. The memory package of claim 4, wherein
the first memory die comprises:
a first side of a first length extending in a first direction; and
a second side of a second length, shorter than the first length, extending in a second direction intersecting the first direction; and
the second memory die comprises:
a third side of the first length extending in the second direction; and
a fourth side of the second length extending in the first direction.

8. The memory package of claim 1, wherein
the first bonding pad and the second bonding pad are in contact via a bump; and
the memory package further comprises a bonding structure comprising the first bonding pad, the second bonding pad, and the bump.

9. The memory package of claim 1, further comprising an interposer between the first bonding pad and the second bonding pad,
wherein the interposer comprises:
an input/output pad connected to the first wire; and
a redistribution structure electrically connecting the input/output pad to the first bonding pad and the second bonding pad.

10. The memory package of claim 1, wherein
each of the first memory die and the second memory die is configured to receive data signals from a first channel, a second channel, a third channel, and a fourth channel, and
the first memory die and the second memory die are configured to receive a first data signal of the first channel via the first wire, the first bonding pad, and the second bonding pad.

11. The memory package of claim 10, wherein
the first memory die and the second memory die comprise a volatile memory device,
the first memory die is configured to operate as a first rank by a first chip selection signal, and
the second memory die is configured to operate as a second rank by a second chip selection signal different from the first chip selection signal.

12. The memory package of claim 10, wherein
the first memory die and the second memory die comprise a non-volatile memory device,
the first memory die is configured to operate as a first way by a first chip selection signal; and
the second memory die is configured to operate as a second way by a second chip selection signal different from the first chip selection signal.

13. A memory package comprising:
a first memory die comprising a first bonding pad;
a second memory die comprising:
a second bonding pad electrically connected to the first bonding pad; and
a first input/output pad connected to the second bonding pad by a first redistribution layer;
a third memory die comprising a third bonding pad;
a fourth memory die comprising:
a fourth bonding pad electrically connected to the third bonding pad; and
a second input/output pad connected to the fourth bonding pad by a second redistribution layer; and
a package substrate comprising a wire pad connected, by a first wire, to the first input/output pad, and the wire pad connected, by a second wire, to the second input/output pad.

14. The memory package of claim 13, wherein
the wire pad is configured to receive a first data signal,
the first memory die and the second memory die are configured to receive the first data signal via the first wire, the first bonding pad, and the second bonding pad, and
the third memory die and the fourth memory die are configured to receive the first data signal via the second wire, the third bonding pad, and the fourth bonding pad.

15. The memory package of claim 13, wherein
the first memory die further comprises a first substrate and a first wiring layer between the first substrate and the first bonding pad,
the second memory die further comprises a second substrate and a second wiring layer between the second substrate and the first redistribution layer;
the third memory die further comprises a third substrate and a third wiring layer between the third substrate and the third bonding pad;
the fourth memory die further comprises a fourth substrate and a fourth wiring layer between the fourth substrate and the second redistribution layer,
a first surface of the first substrate and a second surface of the second substrate face each other,
the first surface and the second surface are active surfaces,
a third surface of the third substrate and a fourth surface of the fourth substrate face each other, and
the third surface and the fourth surface are active surfaces.

16. The memory package of claim 15, wherein
the first memory die, the second memory die, the third memory die, and the fourth memory die are stacked in an order, from the package substrate, of the second memory die, the first memory die, the fourth memory die, and the third memory die.

17. A memory package comprising:
a first memory die comprising:
a first bonding pad configured to receive a first data signal for a first channel;
a second bonding pad configured to receive a second data signal, of a same type as the first data signal, for a second channel different from the first channel;
a third bonding pad configured to receive a third data signal, of the same type as the first data signal, for a third channel different from the first channel;
a fourth bonding pad configured to receive a fourth data signal, of the same type as the first data signal, for a fourth channel different from the first channel; and
a first input/output pad electrically connected to the first bonding pad by a redistribution layer;
a second memory die comprising:
a fifth bonding pad configured to receive the first data signal and electrically connected to the first bonding pad;
a sixth bonding pad configured to receive the second data signal and electrically connected to the second bonding pad;
a seventh bonding pad configured to receive the third data signal and electrically connected to the third bonding pad; and
an eighth bonding pad configured to receive the fourth data signal and electrically connected to the fourth bonding pad; and
a package substrate comprising a first wire connected to the first input/output pad.

18. The memory package of claim 17, wherein
the first memory die further comprises a first substrate and a first wiring layer between the first substrate and each from among the first bonding pad, the second bonding pad, the third bonding pad, and the fourth bonding pad,
the first bonding pad and the third bonding pad are in point symmetry with respect to a center of a first surface of the first substrate, the first surface being an active surface; and
the first bonding pad and the second bonding pad are symmetrical with each other with respect to a first diagonal direction corresponding to a first side of the first surface extending in a first direction and a second side of the first surface extending in a second direction intersecting the first direction, the first side being longer than the second side.

19. The memory package of claim 18, wherein
the first bonding pad, the second bonding pad, the third bonding pad, and the fourth bonding pad overlap with the fifth bonding pad, the sixth bonding pad, the seventh bonding pad, and the eighth bonding, respectively, in a plan view of the memory package.

20. The memory package of claim 18, wherein
the first bonding pad, the second bonding pad, the third bonding pad, and the fourth bonding pad are configured as a same port in a netlist level.
